(19) United States
(12) Patent Application Publication
(10) Pub. No.: US 2024/0014163 A1
(43) Pub. Date: Jan. 11, 2024

(54) SEMICONDUCTOR PACKAGE

(71) Applicant: SAMSUNG ELECTRONICS CO., LTD., Suwon-si (KR)

(72) Inventors: Jong Youn KIM, Suwon-si (KR); Eung Kyu KIM, Suwon-si (KR); Min Jun BAE, Suwon-si (KR); Hyeon Seok LEE, Suwon-si (KR); Seok Kyu CHOI, Suwon-si (KR)

(21) Appl. No.: 18/312,191

(22) Filed: May 4, 2023

(30) Foreign Application Priority Data
Jul. 7, 2022 (KR) 10-2022-0083470

(51) Int. Cl. H01L 23/00; H01L 23/498; H01L 25/16

(52) U.S. Cl. CPC H01L 24/32; H01L 24/16; H01L 24/08; H01L 24/73; H01L 23/49827; H01L 23/49838; H01L 23/49866; H01L 25/162; H01L 2224/08235; H01L 24/48; H01L 2224/26175; H01L 2924/1205; H01L 2224/16168; H01L 2224/32155; H01L 2224/48228; H01L 2224/73204

(57) ABSTRACT

A semiconductor package includes a redistribution substrate having a first side and an opposite second side, a semiconductor chip on the first side of the redistribution substrate, a silicon capacitor on the second side of the redistribution substrate, a plurality of solder balls on the second side of the redistribution substrate and adjacent the silicon capacitor, and a metal pattern in the redistribution substrate and positioned between the silicon capacitor and the solder balls. The metal pattern includes a first portion extending in a first direction, and a second portion connected to the first portion and extending in a second direction different from the first direction.

### CROSS-REFERENCE TO RELATED APPLICATION

This application claims priority under 35 U.S.C. § 119 to Korean Patent Application No. 10-2022-0083470 filed on Jul. 7, 2022 in the Korean Intellectual Property Office, the contents of which are herein incorporated by reference in its entirety.

### BACKGROUND

### 1. Field of the Disclosure

The present disclosure relates to semiconductor packages. More specifically, the present disclosure relates to semiconductor packages configured to reduce contamination of connecting terminals, such as solder balls.

### 2. Description of the Related Art

A semiconductor package is a package in which an integrated circuit chip is implemented in a form suitable for use in an electronic product. Typically, a semiconductor package includes a semiconductor chip mounted on a printed circuit board and electrically connects them using bonding wires or bumps.

Unfortunately, when connecting terminals, such as solder balls, for connecting a semiconductor package and an external substrate are contaminated by underfill, performance and reliability of the semiconductor package may be degraded.

### SUMMARY

Aspects of the present disclosure provide a semiconductor package capable of improving performance and reliability of a product.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a semiconductor package comprising, a redistribution substrate which includes a first side and an opposite second side, a semiconductor chip on the first side of the redistribution substrate, a silicon capacitor on the second side of the redistribution substrate, a plurality of solder balls on the second side of the redistribution substrate and adjacent the silicon capacitor, and a metal pattern in the redistribution substrate and positioned between the silicon capacitor and the solder balls. The metal pattern includes a first portion extending in a first direction, and a second portion connected to the first portion and extending in a second direction different from the first direction.

According to another aspect of the present disclosure, there is provided a semiconductor package comprising, a redistribution substrate which includes a first side and an opposite second side, a semiconductor chip on the first side of the redistribution substrate, a silicon capacitor on the second side of the redistribution substrate, the silicon capacitor having a rectangular shape in plan view. An underfill is provided between the silicon capacitor and the redistribution substrate. A plurality of solder balls are on the second side of the redistribution substrate and adjacent the silicon capacitor. The plurality of solder balls are not in contact with the underfill. A metal pattern is within the redistribution substrate and adjacent a side surface of the silicon capacitor. The metal pattern has a “U” shape in plan view.

According to another aspect of the present disclosure, there is provided a semiconductor package comprising, a redistribution substrate which includes a first side and an opposite second side, a semiconductor chip on the first side of the redistribution substrate, a silicon capacitor on the second side of the redistribution substrate, the silicon capacitor having a rectangular shape in plan view. A plurality of connection members are between the silicon capacitor and the redistribution substrate, and an underfill surrounds the plurality of connecting members between the silicon capacitor and the redistribution substrate. A plurality of solder balls are on the second side of the redistribution substrate and are adjacent the silicon capacitor. A single layer metal pattern is within the redistribution substrate and between the silicon capacitor and the solder balls. The metal pattern is adjacent a side surface of the silicon capacitor and includes a first portion extending in a first direction, and a second portion connected to the first portion and extending in a second direction different from the first direction. A distance from the first side of the redistribution substrate to a bottom surface of the metal pattern is smaller than a distance from the first side of the redistribution substrate to the second side of the redistribution substrate. At least a part of the metal pattern contacts at least a part of the underfill.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is an exemplary plan view for explaining a semiconductor package according to some embodiments.

FIG. 2 is an exemplary cross-sectional view taken along a line A-A of FIG. 1.

FIG. 3 is an enlarged view of a region P of FIG. 1.

FIG. 4 is an enlarged view of a region Q of FIG. 2.

FIGS. 5 to 15 are exemplary plan views for explaining a semiconductor package according to some embodiments.

FIGS. 16 and 17 are exemplary cross-sectional views for explaining a semiconductor package according to some embodiments.

FIGS. 18 and 19 are exemplary cross-sectional views for explaining a semiconductor package according to some embodiments.

FIGS. 20 to 27 are diagrams for explaining the fabricating process of the semiconductor package having the cross section of FIG. 2.

### DETAILED DESCRIPTION OF THE EMBODIMENTS

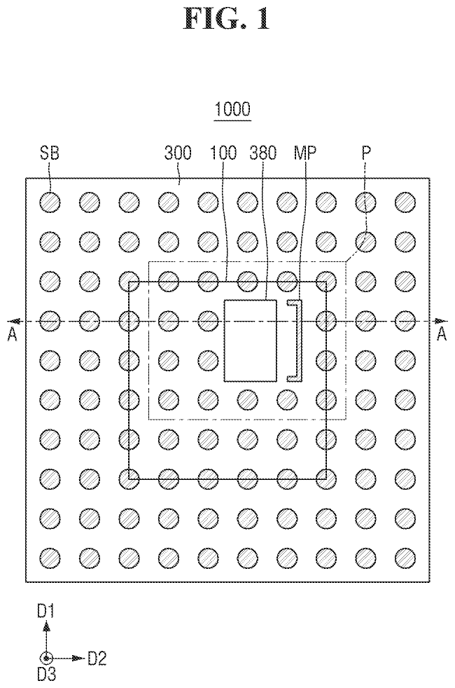

A semiconductor package according to exemplary embodiments will be described below with reference to FIGS. 1 to 19.

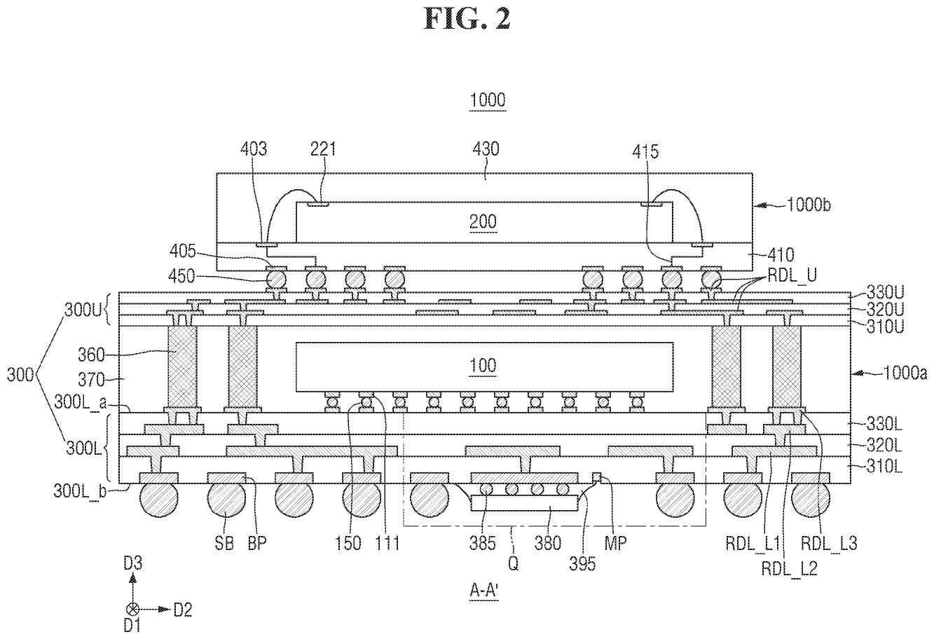

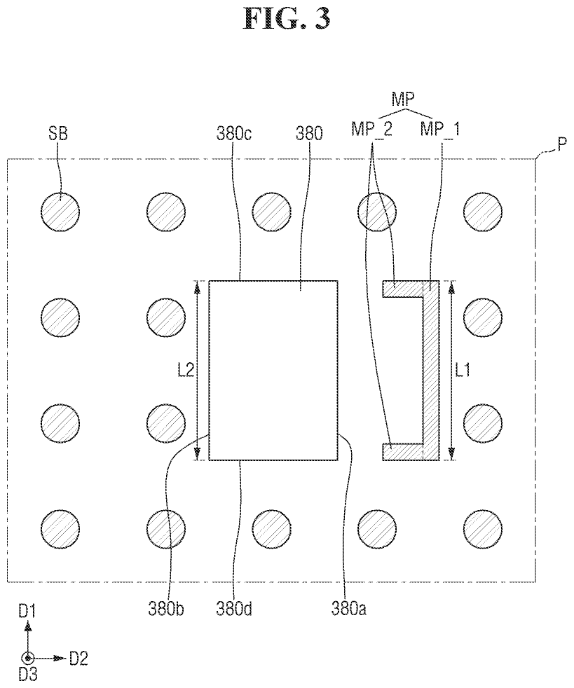

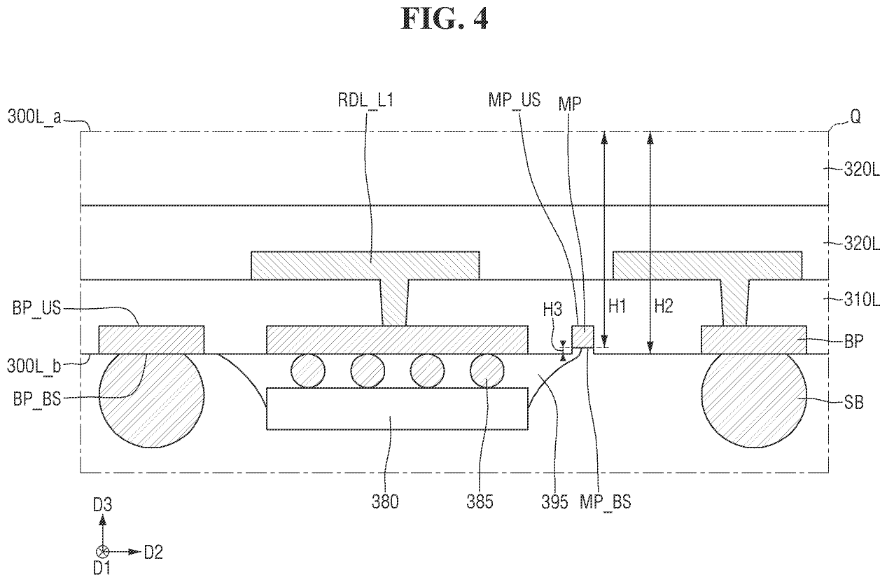

FIG. 1 is an exemplary plan view for explaining a semiconductor package according to some embodiments. FIG. 2 is an exemplary cross-sectional view taken along a line A-A of FIG. 1. FIG. 3 is an enlarged view of a region P of FIG. 1. FIG. 4 is an enlarged view of a region Q of FIG. 2.

First, referring to FIGS. 1 and 2, a semiconductor package 1000 according to some embodiments may include a first semiconductor package 1000a, and a second semiconductor package 1000b provided on the first semiconductor package 1000a.

The first semiconductor package 1000a may include a redistribution substrate 300, a first semiconductor chip 100, a plurality of ball pads BP, a silicon capacitor 380, a plurality of first connection members 385, an underfill 395, a plurality of solder balls SB, and a metal pattern MP.

The redistribution substrate 300 may include a lower redistribution substrate 300L and an upper redistribution substrate 300U. The lower redistribution substrate 300L may be placed below the first semiconductor chip 100. The upper redistribution substrate 300U may be placed on the first semiconductor chip 100.

For example, the lower redistribution substrate 300L may include a first side 300L_a and a second side 300L_b that are opposite to each other. The upper redistribution substrate 300U and the first semiconductor chip 100 may be placed on the first side 300L_a of the lower redistribution substrate 300L. The silicon capacitor 380 may be placed on the second side 300L_b of the lower redistribution substrate 300L. The plurality of solder balls SB may be placed on the second side 300L_b of the lower redistribution substrate 300L. The first side 300L_a may face the first semiconductor chip 100. The second side 300L_b may face the solder ball SB. The second side 300L_b may face the silicon capacitor 380.

In FIG. 1, the plurality of solder balls SB may be placed around and adjacent the silicon capacitor 380, as illustrated. The plurality of solder balls SB may wrap around (i.e., are positioned around the periphery of) the silicon capacitor 380 when viewed in plan view. The metal pattern MP may be placed between some of the solder balls SB and the silicon capacitor 380 on a plane in which a first direction D1 and a second direction D2 extend. The metal pattern MP may include a portion extending in the second direction D2, and a portion extending in the first direction D1. As used herein, the first direction D1, the second direction D2, and the third direction D3 may be different directions from each other. For example, the first direction D1, the second direction D2, and the third direction D3 may intersect each other, but are not limited thereto. The third direction D3 may be a thickness direction of the redistribution substrate 300. The plurality of solder balls SB may be placed on the second side 300L_b of the lower redistribution substrate 300L on the plane in which the first direction D1 and the second direction D2 extend.

In FIG. 2, the lower redistribution substrate 300L may include first to third lower insulating layers 310L, 320L and 330L. First to third lower redistribution patterns RDL_L1, RDL_L2 and RDL_L3, a plurality of ball pads BP, and the metal pattern MP may be placed inside the first to third lower insulating layers 310L, 320L and 330L.

As an example, a first lower insulating layer 310L may wrap or extend around the ball pads BP. The ball pads BP are exposed through one surface of the first lower insulating layer 310L. The ball pads BP may be exposed through the second side 300L_b of the lower redistribution substrate 300L. The first lower insulating layer 310L may wrap or extend around the metal pattern MP. The metal pattern MP may expose one surface of the first lower insulating layer 310L. The metal pattern MP may expose the second side 300L_b of the lower redistribution substrate 300L. The first lower insulating layer 310L may wrap or extend around a via portion of the first lower redistribution pattern RDL_L1. A second lower insulating layer 320L may wrap or extend around a wiring portion of the first lower redistribution pattern RDL_L1. Also, the second lower insulating layer 320L may wrap or extend around the via portion of the second lower redistribution pattern RDL_L2. A third lower insulating layer 330L may wrap or extend around the wiring portion of the second lower redistribution pattern RDL_L2. The third lower insulating layer 330L may wrap or extend around the via portion of the third lower redistribution pattern RDL_L3. However, the technical idea of the present disclosure is not limited thereto.

Each of the first to third lower insulating layers 310L, 320L, and 330L may be made of a photoimageable dielectric. For example, the first to third lower insulating layers 310L, 320L, and 330L may include a photosensitive polymer. The photosensitive polymer may be formed of at least one of, for example, photosensitive polyimide, polybenzoxazole, phenolic polymer, and benzocyclobutene-based polymer. As another example, the first to third lower insulating layers 310L, 320L, and 330L may be formed of silicon oxide film, silicon nitride film or silicon oxynitride film.

Each of the first to third lower redistribution patterns RDL_L1, RDL_L2, and RDL_L3 may include a conductive material. For example, the first to third lower redistribution patterns RDL_L1, RDL_L2, and RDL_L3 may include, but are not limited to, copper (Cu).

In some embodiments, the lower redistribution substrate 300L may include organics. For example, the lower redistribution substrate 300L may include a pre-preg. The pre-preg is a composite fiber in which reinforcing fibers such as carbon fiber, glass fiber or aramid fiber are pre-impregnated with a thermosetting polymer binder (e.g., epoxy resin) or thermoplastic resin. In some embodiments, the lower redistribution substrate 300L may include a copper clad laminate (CCL). For example, the lower redistribution substrate 300L may have a structure in which a copper laminate is laminated on a single side or both sides of a thermoset pre-preg (e.g., pre-preg of C-stage).

The plurality of ball pads BP may be provided inside the lower redistribution substrate 300L. The plurality of ball pads BP may be provided inside the first lower insulating layer 310L. The plurality of ball pads BP may be exposed through the second side 300L_b of the lower redistribution substrate 300L. Bottom surfaces of each of the plurality of ball pads BP may be placed on the same plane as the second side 300L_b of the lower redistribution substrate 300L. In some embodiments, some parts of the plurality of ball pads BP may be connected to the solder ball SB. Other parts of the plurality of ball pads BP may be connected to the silicon capacitor 380. However, the technical idea of the present disclosure is not limited thereto.

Each of the plurality of ball pads BP may include a conductive material. For example, the plurality of ball pads BP may include, but are not limited to, copper (Cu).

The plurality of solder balls SB may be provided on the ball pads BP. The solder ball SB may be connected to the ball pads BP. Although each of the plurality of solder balls SB is shown to have a ball shape, the technical idea of the present disclosure is not limited thereto. Each of the plurality of solder balls SB may have various shapes such as a land, a ball, a pin, and a pillar. The number, interval, placement form, and the like of the plurality of solder balls SB are not limited to those shown in the drawings, and may vary depending on design. Each of the plurality of solder balls SB may be, but is not limited to, a solder bump including low-melting point metals, for example, tin (Sn) and tin (Sn) alloys.

The silicon capacitor 380 may be provided on the second side 300L_b of the lower redistribution substrate 300L. The silicon capacitor 380 may be connected to a ball pad BP. The silicon capacitor 380 may include silicon (Si). As an example, the silicon capacitor 380 may be, but not limited to, a silicon (Si) capacitor. Although a single silicon capacitor 380 is shown in FIG. 2, the number thereof is not limited thereto. The placement and number of silicon capacitors 380 may vary depending on the design.

Although not shown, the semiconductor package 1000 according to some embodiments may further include a multi-layer ceramic capacitor (MLCC). The multi-layer ceramic capacitor may be placed at a position adjacent to the silicon capacitor 380 or may be placed at a position spaced apart from the silicon capacitor 380.

A plurality of first connection members 385 may be provided between the ball pad BP and the silicon capacitor 380. The plurality of first connection members 385 may be connected to the ball pad BP and the silicon capacitor 380. The first semiconductor chip 100 and the silicon capacitor 380 may be electrically connected through the plurality of first connection members 385. The plurality of first connection members 385 may be, but are not limited to, solder bumps including low-melting point metals, for example, tin (Sn) and tin (Sn) alloys. The plurality of first connecting members 385 may have various shapes such as a land, a ball, a pin, and a pillar. The plurality of first connection members 385 may be formed of a single layer or multiple layers. When the plurality of first connection members 385 are formed of a single layer, the plurality of first connection members 385 may include tin-silver (Sn—Ag) solder or copper (Cu) as an example. When the plurality of first connection members 385 are formed of multiple layers, the plurality of first connection members 385 may include copper (Cu) filler and solder as an example. The number, interval, placement form, and the like of the plurality of first connection members 385 are not limited to those shown, and may vary depending on design.

An underfill 395 may be formed between the lower redistribution substrate 300L and the silicon capacitor 380. The underfill 395 may fill a space between the lower redistribution substrate 300L and the silicon capacitor 380. The underfill 395 may wrap (i.e., surround or encase) the plurality of first connection members 385. In some embodiments, at least a part of the underfill 395 may cover at least a part of the metal pattern MP. A part of the metal pattern MP may not be covered with the underfill 395. At least a part of the underfill 395 may overlap at least a part of the metal pattern MP in the third direction D3. A part of the metal pattern MP may not overlap the underfill 395 in the third direction D3. At least a part of the underfill 395 may overlap at least a part of the metal pattern MP in the thickness direction of the redistribution substrate 300.

The underfill 395 may flow along the second side 300L_b of the lower redistribution substrate 300L after being discharged onto the second side 300L_b of the lower redistribution substrate 300L. The underfill 395 may flow between the lower redistribution substrate 300L and the silicon capacitor 380. The underfill 395 may cover a part of the metal pattern MP. However, the underfill 395 does not flow completely over the metal pattern MP. The underfill 395 does not completely cover the metal pattern MP. This may be due to a difference in physical properties between the second side 300L_b of the lower redistribution substrate 300L and the metal pattern MP. The wettability of the lower redistribution substrate 300L and the wettability of the metal pattern MP are different.

Because the underfill 395 does not flow over the metal pattern MP, the underfill 395 may not come into contact with the solder balls SB that are adjacent to the capacitor 380. Thus, the solder balls SB adjacent to the capacitor 380 may not be contaminated by the underfill 395. Therefore, a semiconductor package with improved reliability and performance can be fabricated. The underfill 395 may include, but is not limited to, an insulating polymeric material such as EMC (epoxy molding compound).

In an embodiment, the underfill 395 may be discharged after the solder ball SB lands first. Since the underfill 395 does not flow over the metal pattern MP, the solder ball SB may not be contaminated by the underfill 395. In another embodiment, the underfill 395 may be discharged first before the solder ball SB lands. In this case, since the underfill 395 does not flow over the metal pattern MP, the ball pad BP may be prevented from being contaminated by the underfill 395. Therefore, a semiconductor package with improved reliability and performance can be fabricated.

The metal pattern MP may be provided inside the lower redistribution substrate 300L. The metal pattern MP may be formed of a single layer. However, the technical idea of the present disclosure is not limited thereto. The metal pattern MP may be formed of multiple layers. The metal pattern MP may include, for example, copper (Cu).

The metal pattern MP, the silicon capacitor 380, and the underfill 395 according to some embodiments will be described in more detail below with reference to FIGS. 3 and 4.

Referring to FIGS. 3 and 4, the silicon capacitor 380 may have a rectangular shape when viewed in plan view. For example, the silicon capacitor 380 may include first to fourth side surfaces 380a, 380b, 380c and 380d, as illustrated in FIG. 3.

A first surface 380a and a second surface 380b may extend in the first direction D1. The first surface 380a and the second surface 380b may be opposite to each other. A third surface 380c may connect the first surface 380a and the second surface 380b. The third surface 380c may extend in the second direction D2. A fourth surface 380d may connect the first surface 380a and the second surface 380b. The fourth surface 380d may extend in the second direction D2. The third surface 380c and the fourth surface 380d may be opposite to each other.

In FIG. 3, although the lengths of each of the first surface 380a and the second surface 380b are shown as being longer than the lengths of the third surface 380c and the fourth surface 380d, the technical idea of the present disclosure is not limited thereto. The lengths of the first surface 380a and the second surface 380b may be shorter than the lengths of the third surface 380c and the fourth surface 380d, and the lengths of the first side to the fourth surface 380a, 380b, 380c and 380d may all be the same.

In some embodiments, the metal pattern MP may be provided adjacent to only the first surface 380a of the silicon capacitor 380, as illustrated in FIG. 3. A metal pattern MP may not be provided adjacent the second surface 380b of the silicon capacitor 380, the third surface 380c of the silicon capacitor 380, and the fourth surface 380d of the silicon capacitor 380. That is, the metal pattern MP may be placed near one surface of the silicon capacitor 380, but may not be placed near the other surfaces.

In some embodiments, the shape of the metal pattern MP may be a “U” shape in plan view, as illustrated in FIG. 3. In the illustrated embodiment of FIG. 3, the metal pattern MP has a “U” shape rotated counterclockwise by 90 degrees.

In other embodiments, the metal pattern MP may have a “U” shape rotated clockwise by 90 degrees, or rotated by 180 degrees. The shape of the metal pattern MP may be changed variously depending on the design, and is not limited to a particular shape or orientation.

The metal pattern MP may include a first portion MP_1 extending in the first direction D1 and a second portion MP_2 extending in the second direction D2, as illustrated in FIG. 3. The first part MP_1 and the second part MP_2 may be connected to each other. The second portion MP_2 may extend in the second direction D2 from each of one end and the other end of the first portion MP_1, as illustrated in FIG. 3.

In some embodiments, the second portion MP_2 of the metal pattern MP may be provided between the first portion MP_1 and the silicon capacitor 380. The second portion MP_2 of the metal pattern MP may extend from the first portion MP_1 toward the silicon capacitor 380 in the second direction D2.

In some embodiments, the length of the first portion MP_1 in the first direction D1 may be greater than the length of the second portion MP_2 in the second direction D2. However, the technical idea of the present disclosure is not limited thereto, and the length of the first portion MP_1 in the first direction D1 may be smaller than the length of the second portion MP_2 in the second direction D2.

The first surface 380a of the silicon capacitor 380 and the metal pattern MP may be spaced apart from each other in the second direction D2. As an example, a distance between the first surface 380a of the silicon capacitor 380 and the metal pattern MP may be, but is not limited to, 50 μm or more and 1000 μm or less.

In some embodiments, a space between the metal pattern MP and the silicon capacitor 380 may be a region from which the underfill 395 is discharged. After the underfill 395 is discharged into the space between the metal pattern MP and the silicon capacitor 380, the discharged underfill 395 may not flow over the metal pattern MP toward the solder balls SB adjacent to the metal pattern MP.

In some embodiments, the first length L1 of the metal pattern MP in the first direction D1 may be the same as the second length L2 of the silicon capacitor 380 in the first direction D1. However, the technical idea of the present disclosure is not limited thereto, and the first length L1 of the metal pattern MP in the first direction D1 may be smaller or greater than the first length L2 of the silicon capacitor 380 in the first direction D1.

In some embodiments, an upper surface MP_US of the metal pattern MP may be placed on the same plane as (i.e., coplanar with) an upper surface BP US of the ball pad BP. The metal pattern MP may be formed in the first recess (not shown). The ball pad BP may be formed in a second recess (not shown). The first recess and the second recess may be formed in the same process. Therefore, the upper surface MP_US of the metal pattern MP may be placed on the same plane as (i.e., coplanar with) the upper surface BP US of the ball pad BP.

However, a bottom surface MP_BS of the metal pattern MP is not placed on the same plane as (i.e., coplanar with) a bottom surface BP_BS of the ball pad BP. The bottom surface BP_BS of the ball pad BP may be placed on the same plane as (i.e., coplanar with) the second side 300L_b of the lower redistribution substrate 300L. The bottom surface MP_BS of the metal pattern MP may be placed between the first side 300L_a of the lower redistribution substrate 300L and the second side 300L_b of the lower redistribution substrate 300L.

For example, a first distance or height H1 in the third direction D3 from the first side 300L_a of the lower redistribution substrate 300L to the bottom surface MP_BS of the metal pattern MP is smaller than a second distance or height H2 in the third direction D3 from the first side 300L_a of the lower redistribution substrate 300L to the second side 300L_b of the lower redistribution substrate 300L, as illustrated in FIG. 4. That is, the first height H1 in the third direction D3 from the first side 300L_a of the lower redistribution substrate 300L to the bottom surface MP_BS of the metal pattern MP is smaller than a thickness of the lower redistribution substrate 300L.

A third height H3 in the third direction D3 from the bottom surface MP_BS of the metal pattern MP to the second side 300L_b of the lower redistribution substrate 300L may be 5 μm or less. A part of the metal pattern MP may be etched during the process of forming the metal pattern MP. Accordingly, the bottom surface MP_BS of the metal pattern MP may be placed between the first side 300L_a of the lower redistribution substrate 300L and the second side 300L_b of the lower redistribution substrate 300L. However, the technical idea of the present disclosure is not limited thereto.

In some embodiments, at least a part of the underfill 395 may overlap at least a part of the metal pattern MP in the third direction D3. At least a part of the underfill 395 may cover at least a part of the bottom surface MP_BS of the metal pattern MP. A part of the underfill 395 may overlap the lower redistribution substrate 300L in the second direction D2. Since the bottom surface MP_BS of the metal pattern MP and the second side 300L_b of the lower redistribution substrate 300L have different levels from each other, a part of the underfill 395 may be placed between the bottom surface MP_BS of the metal pattern MP and the second side 300L_b of the lower redistribution substrate 300L.

In some embodiments, a distance between the first surface 380a of the silicon capacitor 380 and the solder ball SB nearest to the first surface 380a of the silicon capacitor 380 may be greater than a distance between the second surface 380b of the silicon capacitor 380 and the solder ball SB nearest to the second surface 380b of the silicon capacitor 380, as illustrated in FIG. 3. A region between the first surface 380a of the silicon capacitor 380 and the solder ball SB nearest to the first surface 380a of the silicon capacitor 380 may be a region into which the underfill 395 is discharged. The metal pattern MP may be provided in the region between the first surface 380a of the silicon capacitor 380 and the solder ball SB nearest to the first surface 380a of the silicon capacitor 380.

Referring to FIG. 2 again, the semiconductor package 1000 according to some embodiments may further include a plurality of metal pillars 360, a molding film 370, a plurality of first chip pads 111, and a plurality of second connection members 150.

The first semiconductor chip 100 may be mounted on the first side 300L_a of the lower redistribution substrate 300L. The first semiconductor chip 100 may be placed in a central region of the lower redistribution substrate 300L when viewed in plan view.

The first chip pads 111 may be provided on the lower surface of the first semiconductor chip 100. The lower surface of the first semiconductor chip 100 may be placed to face the first side 300L_a of the lower redistribution substrate 300L. The first chip pads 111 of the first semiconductor chip 100 may be connected to the third lower redistribution pattern RDL_L3.

The second connection members 150 may be attached between the first chip pads 111 of the first semiconductor chip 100 and the third lower redistribution pattern RDL_L3. The first semiconductor chip 100 and the solder balls SB may be electrically connected through the second connection members 150. The second connection members 150 may be, but not limited to, solder bumps including low-melting point metals, for example, tin (Sn) and tin (Sn) alloys. The second connecting members 150 may have various shapes such as a land, a ball, a pin, and a pillar. The second connection members 150 may be formed of a single layer or multiple layers. When the second connection members 150 are formed of a single layer, the second connection members 150 may include tin-silver (Sn—Ag) solder or copper (Cu) as an example. When the second connection members 150 are formed of multiple layers, the second connection members 150 may include copper (Cu) filler and solder as an example. The number, interval, placement form, and the like of the second connection members 150 are not limited to those shown in the drawings, and may vary depending on the design.

Metal pillars 360 may be provided around the first semiconductor chip 100. The metal pillars 360 may electrically connect the lower redistribution substrate 300L and the upper redistribution substrate 300U. The metal pillars 360 may penetrate through the molding film 370. The upper surfaces of the metal pillars 360 may form the same surface as the upper surface of the molding film 370 (i.e., the upper surfaces of the metal pillars 360 may be coplanar with the upper surface of the molding film 370). The lower surfaces of the metal pillars 360 may come into contact with the third lower redistribution patterns RDL_L3 of the lower redistribution substrate 300L.

The molding film 370 may be provided between the lower redistribution substrate 300L and the upper redistribution substrate 300U. The molding film 370 may cover the first semiconductor chip 100. The molding film 370 may be provided on the first side 300L_a of the lower redistribution substrate 300L. The molding film 370 may cover side walls and the upper surface of the first semiconductor chip 100. The molding film 370 may fill between the metal pillars 360. The thickness of the molding film 370 may be substantially the same as the thicknesses of the metal pillars 360. The molding film 370 may include an insulating polymer such as an epoxy-based molding compound.

The upper redistribution substrate 300U may include first to third upper insulating layers 310U, 320U and 330U, and upper redistribution patterns RDL_U inside the first to third upper insulating layers 310U, 320U and 330U. The first to third upper insulating layers 310U, 320U and 330U may include the same material as those included in the first to third lower insulating layers 310L, 320L and 330L.

For example, each of the first to third upper insulating layers 310U, 320U, and 330U may be made up of a photoimageable dielectric. The first to third upper insulating layers 310U, 320U and 330U may include a photosensitive polymer. The photosensitive polymer may be formed of at least one of, for example, photosensitive polyimide, polybenzoxazole, phenolic polymer, and benzocyclobutene-based polymer. As another example, the first to third upper insulating layers 310U, 320U and 330U may be formed of silicon oxide film, silicon nitride film or silicon oxynitride film.

The upper redistribution patterns RDL_U may include the same material as those of the first to third lower redistribution patterns RDL_L1, RDL_L2, and RDL_L3. For example, the upper redistribution patterns RDL_U may include, but are not limited to, copper (Cu).

A second semiconductor package 1000b may be placed on the upper redistribution substrate 300U. The second semiconductor package 1000b may include a circuit board 410, a second semiconductor chip 200, and an upper molding film 430. The circuit board 410 may be, but is not limited to, a printed circuit board. A lower conductive pad 405 may be placed on the lower surface of the circuit board 410.

A second semiconductor chip 200 may be placed on the circuit board 410. The second semiconductor chip 200 may include integrated circuits. The integrated circuits may include a memory circuit, a logic circuit or a combination thereof. The second chip pads 221 of the second semiconductor chip 200 may be electrically connected to the upper conductive pad 403 on the upper surface of the circuit board 410 by wire bonding. The upper conductive pad 403 on the upper surface of the circuit board 410 may be electrically connected to the lower conductive pad 405 through an internal wiring 415 inside the circuit board 410.

An upper molding film 430 may be provided on the circuit board 410. The upper molding film 430 may cover the second semiconductor chip 200. The upper molding film 430 may include an insulating polymer such as an epoxy-based polymer.

The semiconductor package 1000 according to some embodiments may further include a plurality of third connection members 450. The third connection members 450 may be provided between the lower conductive pad 405 of the circuit board 410 and the upper redistribution pattern RLD_U. The third connection members 450 may be, but are not limited to, solder bumps including low-melting point metals, for example, tin (Sn) and tin (Sn) alloys. The third connection members 450 may have various shapes such as a land, a ball, a pin, and a pillar. The third connection members 450 may be formed of a single layer or multiple layers. When the third connection members 450 are formed of a single layer, the third connection members 450 may include, for example, tin-silver (Sn—Ag) solder or copper (Cu). When the third connection members 450 are formed of multiple layers, the third connection members 450 may include copper (Cu) filler and solder as an example. The number, interval, placement form and the like of the third connection members 450 are not limited to those shown in the drawings, and may vary depending on the design.

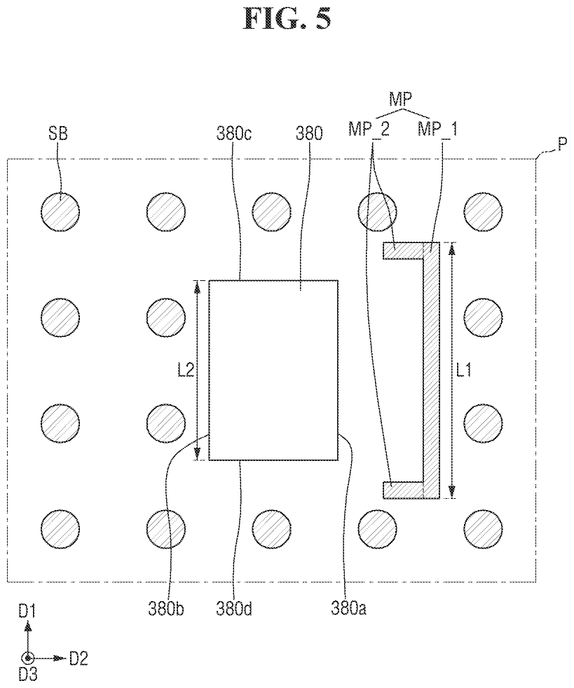

FIGS. 5 to 15 are exemplary plan views for explaining a semiconductor package according to some embodiments. Various embodiments of the semiconductor packages will be described below with reference to FIGS. 5 to 15.

Referring to FIG. 5 first, the first length L1 in the first direction D1 of the first portion MP_1 of the metal pattern MP may be greater than the second length L2 in the first direction D1 of the silicon capacitor 380. The silicon capacitor 380 may completely overlap the first portion MP_1 of the metal pattern MP in the second direction D2. In other words, because the metal pattern MP has a first length L1 that is greater than the second length L2 of the silicon capacitor 380, the metal pattern MP provides a more effective barrier by helping prevent the underfill from flowing around the ends of the metal pattern MP.

Therefore, the metal pattern MP may control (i.e., contain or confine) the flow of the underfill 395 more effectively.

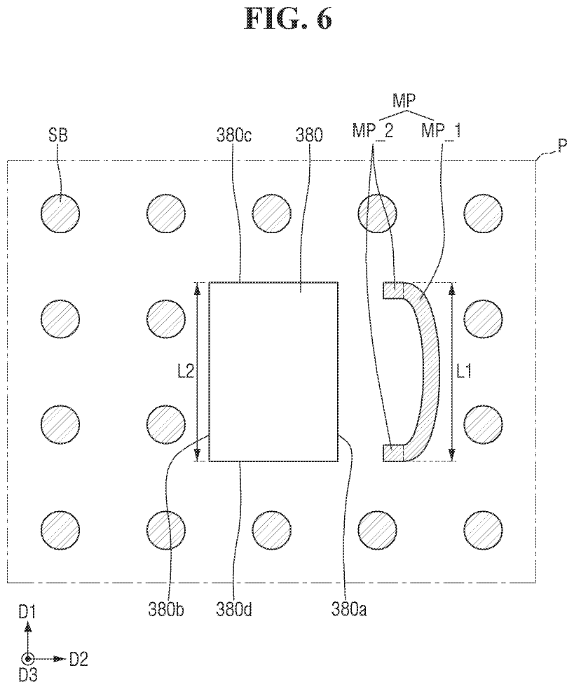

Referring to FIG. 6, the first portion MP_1 of the metal pattern MP may be concave with respect to the first surface 380a of the silicon capacitor 380, as illustrated.

In some embodiments, the second portion MP_2 extends in the second direction D2 at one end and the other end of the first portion MP_1. The first portion MP_1 extends in a different direction from the second portion MP_2. The first portion MP_1 may have a curved shape. In other words, the distance in the second direction D2 from the silicon capacitor 380 to the first portion MP_1 of the metal pattern MP may gradually increase and then decrease from the third surface 380c to the fourth surface 380d of the silicon capacitor 380. However, the technical idea of the present disclosure is not limited thereto.

The shape of the metal pattern MP may be a “U” shape when viewed in plan view. The shape of the metal pattern MP may be a “U” shape rotated counterclockwise by 90 degrees, as illustrated in FIG. 6.

A first length L1 of the metal pattern MP in the first direction D1 may be the same as a second length L2 of the silicon capacitor 380 in the first direction D1.

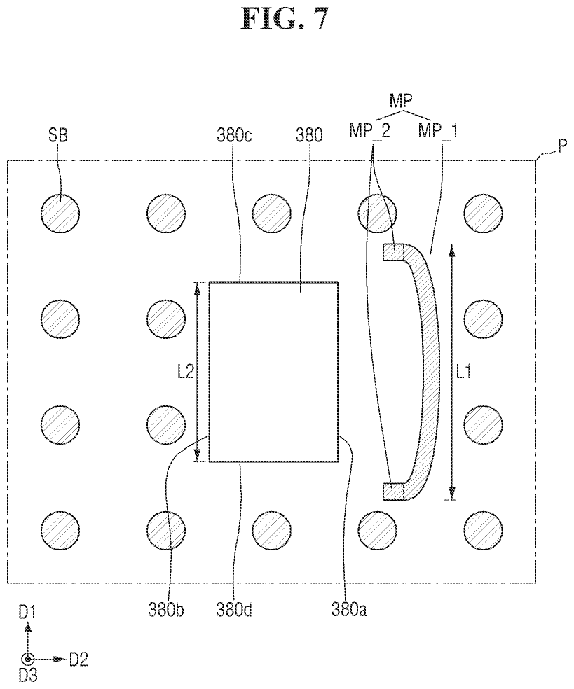

Referring to FIG. 7, the first portion MP_1 of the metal pattern MP may be concave with respect to the first surface 380a of the silicon capacitor 380, as illustrated. The first portion MP_1 of the metal pattern MP may have a curved shape.

Also, the first length L1 in the first direction D1 of the first portion MP_1 of the metal pattern MP may be greater than the second length L2 in the first direction D1 of the silicon capacitor 380. As such, because the metal pattern MP has a first length L1 that is greater than the second length L2 of the silicon capacitor 380, the metal pattern MP provides a more effective barrier by helping prevent the underfill from flowing around the ends of the metal pattern MP.

Therefore, the metal pattern MP may control (i.e., contain or confine) the flow of the underfill 395 more effectively.

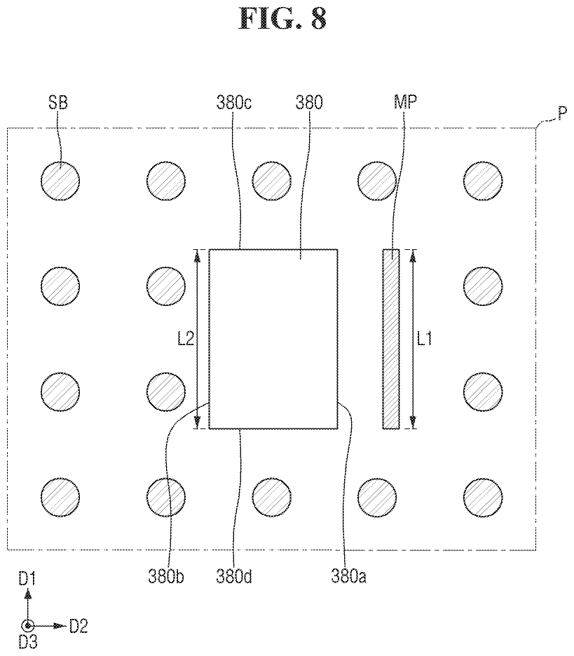

Referring to FIG. 8, the metal pattern MP may not include a second portion. The metal pattern MP may include only a first portion. The metal pattern MP may extend long in the first direction D1. The metal pattern MP may have an “I” shape (i.e., an elongate rectangular shape) when viewed in plan view, as illustrated in FIG. 8. The first length L1 of the metal pattern MP in the first direction D1 may be the same as the second length L2 of the silicon capacitor 380 in the first direction D1.

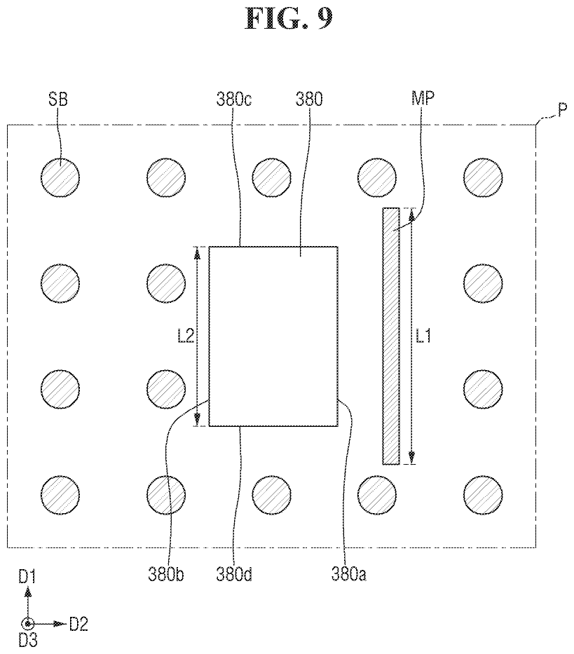

Referring to FIG. 9, the metal pattern MP may not include a second portion. The metal pattern MP may include only a first portion. The metal pattern MP may extend long in the first direction D1. The metal pattern MP may have an “I” shape (i.e., an elongate rectangular shape) when viewed in plan view, as illustrated in FIG. 9.

In some embodiments, the first length L1 of the metal pattern MP in the first direction D1 is greater than the second length L2 of the silicon capacitor 380 in the first direction D1. Therefore, the metal pattern MP may effectively control (i.e., contain or confine) the flow of the underfill 395. In other words, because the metal pattern MP has a first length L1 that is greater than the second length L2 of the silicon capacitor 380, the metal pattern MP provides a more effective barrier by helping prevent the underfill from flowing around the ends of the metal pattern MP.

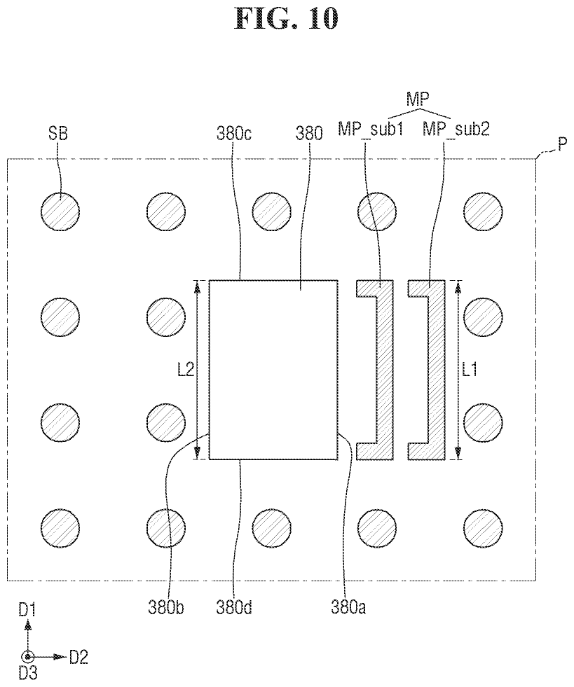

Referring to FIG. 10, the metal pattern MP may include a first sub-pattern MP_sub1 and a second sub-pattern MP_sub2.

The first sub-pattern MP_sub1 and the second sub-pattern MP_sub2 may be spaced apart from each other in the second direction D2. The first sub-pattern MP_sub1 and the second sub-pattern MP_sub2 may be adjacent the first surface 380a of the silicon capacitor 380, as illustrated in FIG. 10. A spaced distance between the first sub-pattern MP_sub1 and the first surface 380a of the silicon capacitor 380 is smaller than a distance between the second sub-pattern MP_sub2 and the first surface 380a of the silicon capacitor 380. That is, the first sub-pattern MP_sub1 may be closer to the silicon capacitor 380 than the second sub-pattern MP_sub2.

In some embodiments, the shapes of the first sub-pattern MP_sub1 and the second sub-pattern MP_sub2 may be the same. For example, the shapes of the first sub-pattern MP_sub1 and the second sub-pattern MP_sub2 may each be a “U” shape rotated counterclockwise by 90 degrees when viewed in plan view. However, the technical idea of the present disclosure is not limited thereto.

The first sub-pattern MP_sub1 may primarily control (i.e., contain or confine) the flow of the underfill 395. The second sub-pattern MP_sub2 may secondarily control (i.e., contain or confine) the flow of the underfill 395. This is because the second sub-pattern MP_sub2 can further contain or confine any underfill that is not contained or confined by the first sub-pattern MP_sub1.

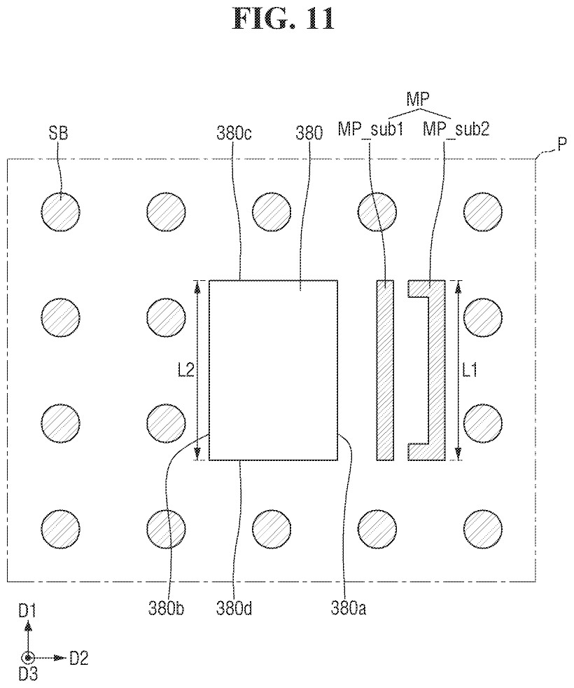

Referring to FIG. 11, the shapes of the first sub-pattern MP_sub1 and the second sub-pattern MP_sub2 may be different from each other, as illustrated.

For example, the shape of the first sub-pattern MP_sub1 may be an “I” shape (i.e., an elongate, rectangular shape), and the shape of the second sub-pattern MP_sub2 may be a “U” shape. However, the technical idea of the present disclosure is not limited thereto. The shape of the first sub-pattern MP_sub1 may be a “U” shape, and the shape of the second sub-pattern MP_sub2 may be an “I” shape, in other embodiments, for example.

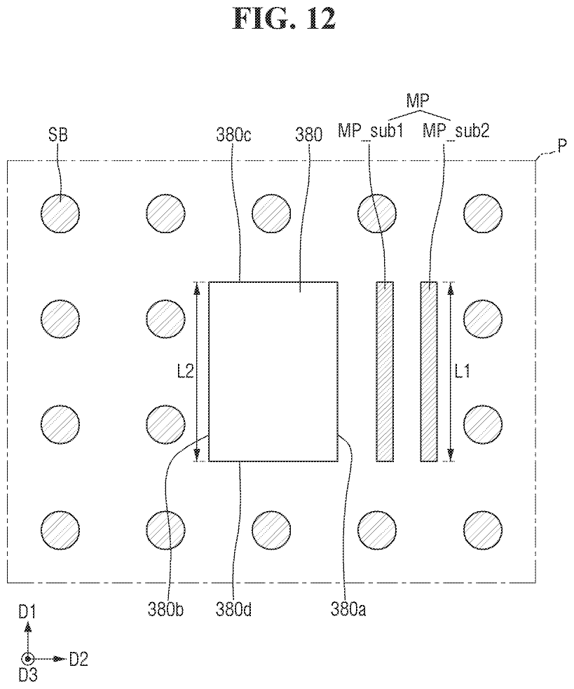

Referring to FIG. 12, the shapes of the first sub-pattern MP_sub1 and the second sub-pattern MP_sub2 may be the same. For example, the shapes of the first sub-pattern MP_sub1 and the second sub-pattern MP_sub2 may each be an “I” shape (i.e., an elongate rectangular shape) when viewed in plan view.

The first sub-pattern MP_sub1 may primarily control the flow of the underfill 395. The second sub-pattern MP_sub2 may secondarily control the flow of the underfill 395. Therefore, the metal pattern MP may control the flow of the underfill 395 more effectively.

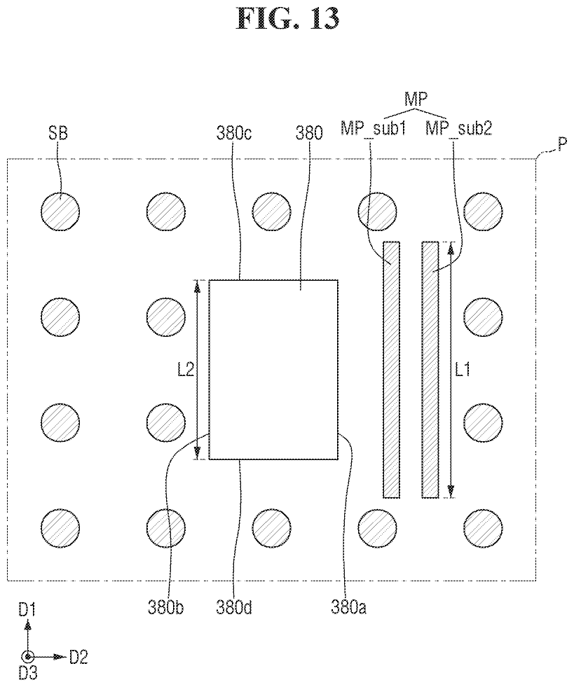

Referring to FIG. 13, the metal pattern MP may include the first sub-pattern MP_sub1 and the second sub-pattern MP_sub2.

The shapes of the first sub-pattern MP_sub1 and the second sub-pattern MP_sub2 may each be an “I” shape (i.e., an elongate rectangular shape) when viewed in plan view. Also, the first length L1 of the metal pattern MP in the first direction D1 is longer than the second length L2 of the silicon capacitor 380 in the first direction D1. The metal pattern MP completely overlaps the silicon capacitor 380 in the second direction D2. In other words, because the metal pattern MP has a first length L1 that is greater than the second length L2 of the silicon capacitor 380, the metal pattern MP provides a more effective barrier by helping prevent the underfill from flowing around the ends of the metal pattern MP. As the metal pattern MP has the aforementioned structure, the flow of underfill 395 can be effectively controlled (i.e., contained or confined).

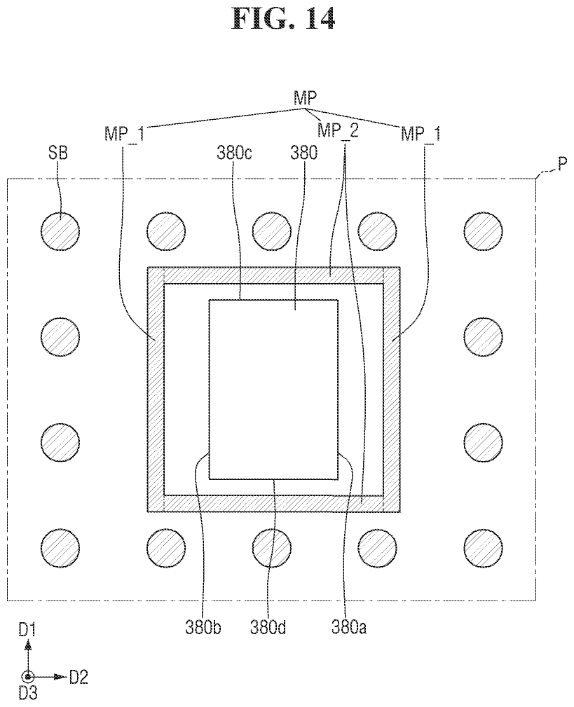

Referring to FIG. 14, the metal pattern MP may have a rectangular shape from the planar viewpoint. The metal pattern MP may surround the first surface 380a, the second surface 380b, the third surface 380c, and the fourth surface 380d of the silicon capacitor 380.

For example, the first portion MP_1 of the metal pattern MP extends in the first direction D1 adjacent the first surface 380a and the second surface 380b of the silicon capacitor 380. The second portion MP_2 of the metal pattern MP extends in the second direction D2 adjacent the third surface 380c and the fourth surface 380d of the silicon capacitor 380. The first portion MP_1 of the metal pattern MP and the second portion MP_2 of the metal pattern MP are connected to each other. That is, the metal pattern MP may have a closed curve shape.

Since the metal pattern MP has a structure that completely surrounds the silicon capacitor 380, the flow of the underfill 395 toward the solder balls SB on all sides of the capacitor 380 can be effectively controlled (i.e., contained or confined).

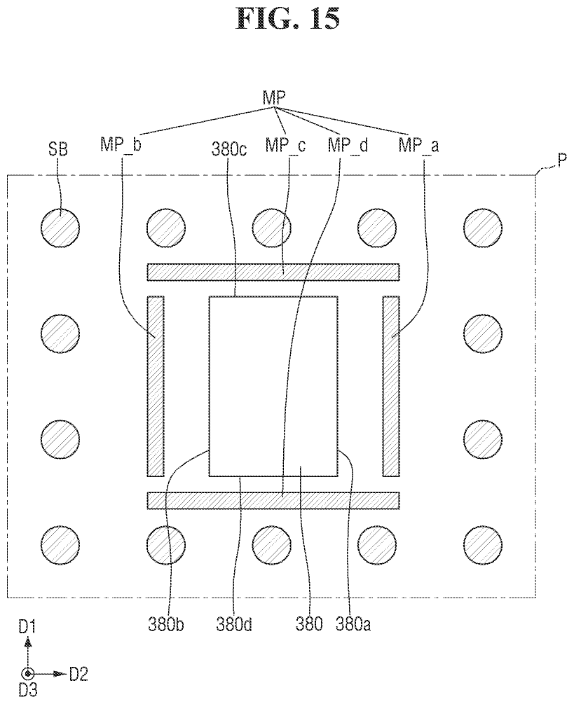

Referring to FIG. 15, the metal pattern MP may include a first pattern MP_a, a second pattern MP b, a third pattern MP_c, and a fourth pattern MP_d.

The first pattern MP_a of the metal pattern MP may be provided adjacent the first surface 380a of the silicon capacitor 380. The second pattern MP b of the metal pattern MP may be provided adjacent the second surface 380b of the silicon capacitor 380. The first pattern MP_a of the metal pattern MP and the second pattern MP b of the metal pattern MP may be symmetrical with each other on the basis of the center of the silicon capacitor 380. The third pattern MP_c of the metal pattern MP may be provided adjacent the third surface 380c of the silicon capacitor 380. The fourth pattern MP_d of the metal pattern MP may be provided adjacent the fourth surface 380d of the silicon capacitor 380. The third pattern MP_c of the metal pattern MP and the fourth pattern MP_d of the metal pattern MP may be symmetrical with each other on the basis of the center of the silicon capacitor 380.

As the metal pattern MP according to some embodiments includes the second pattern MP b, it is possible to more effectively control the flow of the underfill 395 from the second surface 380b of the silicon capacitor 380 toward the solder balls SB adjacent to the second pattern MP b. Since the metal pattern MP includes the third pattern MP_c, it is possible to more effectively control the flow of the underfill 395 from the third surface 380c of the silicon capacitor 380 toward the solder balls SB adjacent to the third pattern MP_c. Since the metal pattern MP includes the fourth pattern MP_d, it is possible to more effectively control the flow of the underfill 395 from the fourth surface 380d of the silicon capacitor 380 toward the solder balls SB adjacent to the fourth pattern MP_d.

In some embodiments, the first pattern MP_a and the second pattern MP b may extend in the first direction D1. The third pattern MP_c and the fourth pattern MP_d may extend in the second direction D2. That is, although each of the first pattern MP_a, the second pattern MP b, the third pattern MP_c, and the fourth pattern MP_d is shown to have an “I” shape, the technical concept of the present disclosure is not limited thereto.

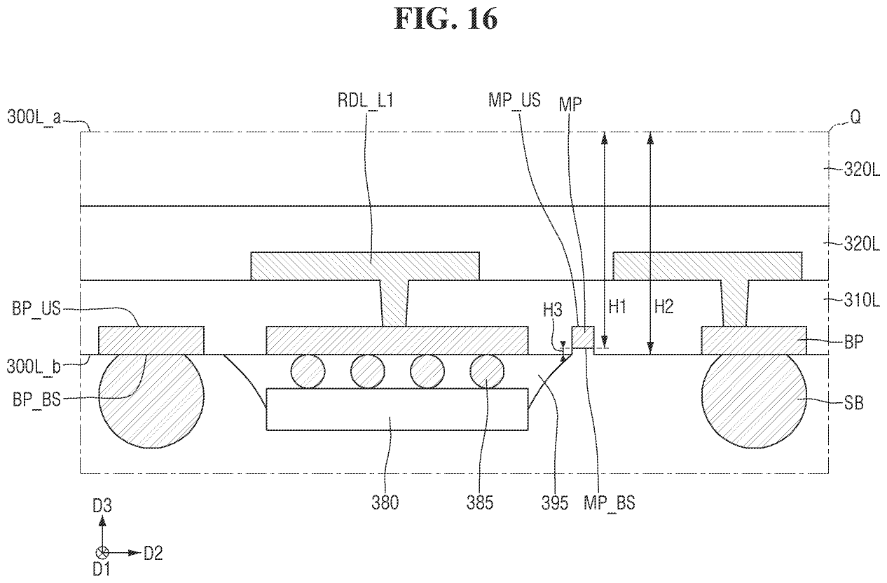

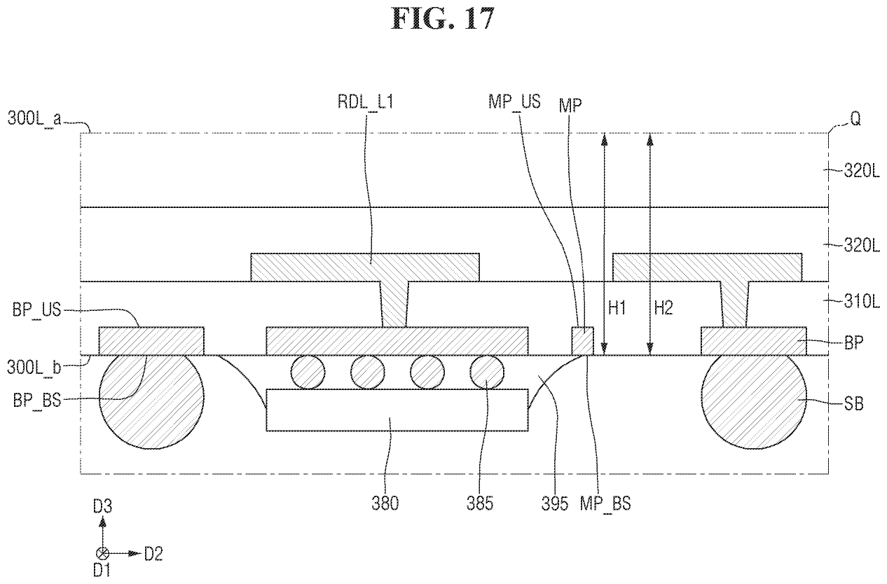

FIGS. 16 and 17 are exemplary cross-sectional views for explaining a semiconductor package according to some embodiments. Various embodiments of semiconductor packages are described below with reference to FIGS. 16 and 17.

First, referring to FIG. 16, the underfill 395 does not completely cover the bottom surface MP_BS of the metal pattern MP.

The underfill 395 may not completely overlap the metal pattern MP in the third direction D3. The underfill 395 may not completely overlap the metal pattern MP in the thickness direction of the redistribution substrate 300. The underfill 395 does not overlap the lower redistribution substrate 300L in the second direction D2. The underfill 395 may not overlap the first lower insulating layer 310L in the second direction D2.

Referring to FIG. 17, the bottom surface MP_BS of the metal pattern MP may be placed on the same plane as (i.e., coplanar with) the second side 300L_b of the lower redistribution substrate 300L. The bottom surface MP_BS of the metal pattern MP may be placed on the same plane as (i.e., coplanar with) the bottom surface BP_BS of the ball pad BP.

A first distance or height H1 from the bottom surface MP_BS of the metal pattern MP to the first side 300L_a of the lower redistribution substrate 300L may be the same as a second distance or height H2 from the second side 300L_b of the lower redistribution substrate 300L to the first side 300L_a of the lower redistribution substrate 300L.

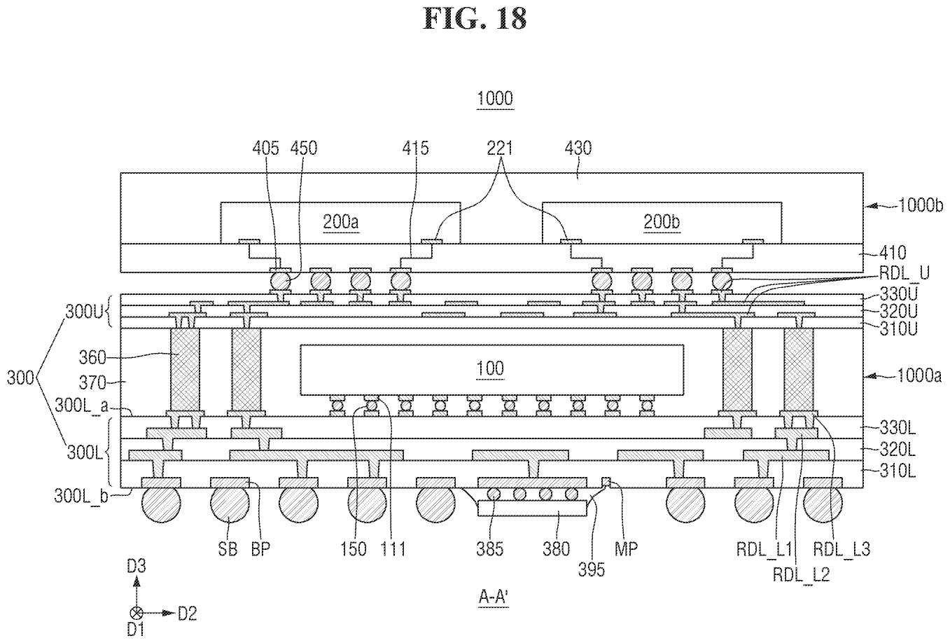

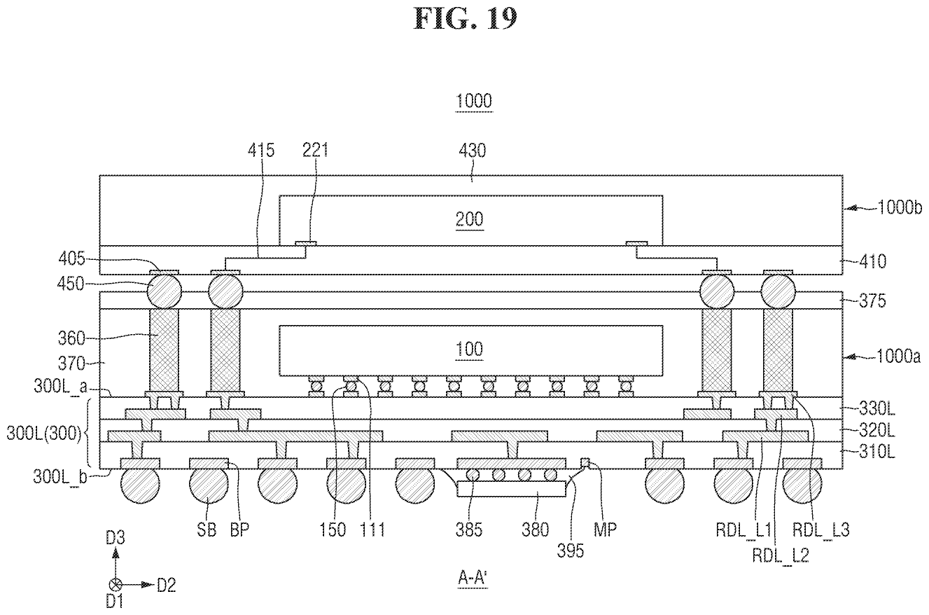

FIGS. 18 and 19 are exemplary cross-sectional views for explaining a semiconductor package according to some embodiments. Various embodiments of the semiconductor package will be described below with reference to FIGS. 18 and 19.

First, referring to FIG. 18, the second semiconductor package 1000b may include two second semiconductor chips 200a and 200b. That is, the second semiconductor chip may include a first sub-semiconductor chip 200a and a second sub-semiconductor chip 200b.

The first sub-semiconductor chip 200a and the second sub-semiconductor chip 200b may be spaced apart from each other. The first sub-semiconductor chip 200a and the second sub-semiconductor chip 200b may be separated from each other by an upper molding film 430. Each of the first sub-semiconductor chip 200a and the second sub-semiconductor chip 200b may include second chip pads 221 on the lower surfaces thereof. The second semiconductor package 1000b does not include the upper conductive pad 403 shown in the embodiment of FIG. 2. As an example, the second chip pads 221 may be electrically connected to the lower conductive pad 405 through the internal wiring 415 inside the circuit board 410.

Although FIG. 18 shows that the first and second sub-semiconductor chips 200a and 200b are provided on the upper surface of the circuit board 410 at the same level, the first sub-semiconductor chip 200a and the second sub-semiconductor chip 200b may be sequentially stacked on the upper surface of the circuit board 410.

Referring to FIG. 19, unlike the embodiment shown in FIG. 2, the upper package substrate may be omitted from the first semiconductor package 1000a.

More specifically, an upper insulating layer 375 may be provided on the molding film 370. The upper insulating layer 375 may include an insulating material. For example, the upper insulating layer 375 may include, but is not limited to, at least one of silicon oxide, silicon nitride, silicon oxynitride, and a low dielectric constant (low-k) material having a dielectric constant lower than that of silicon oxide.

The third connection members 450 may be provided between the lower conductive pad 405 of the circuit board 410 and the metal pillars 360 of the first semiconductor package 1000a. A part of the third connecting members 450 may be placed inside the upper insulating layer 375, as illustrated. One surface of the third connection members 450 may be connected to the lower conductive pad 405, and the other surface of the third connection members 450 may be connected to the metal pillars 360. Therefore, the first semiconductor package 1000a and the second semiconductor package 1000b may be electrically connected to each other.

The second semiconductor chip 200 may be placed on the circuit board 410. The second chip pads 221 of the second semiconductor chip 200 may come into contact with the upper surface of the circuit board 410. The second chip pads 221 of the second semiconductor chip 200 may be electrically connected to the lower conductive pads 405 through the internal wiring 415 in the circuit board 410.

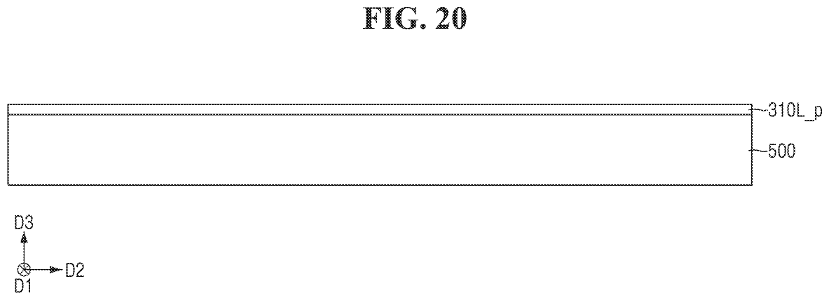

FIGS. 20 to 27 are diagrams for explaining the fabricating process of the semiconductor package having the cross section of FIG. 2. A method for fabricating a semiconductor package according to some embodiments will be described below with reference to FIGS. 20 to 27.

Referring to FIG. 20, a carrier substrate 500 may be provided. The carrier substrate 500 may include a glass. A pre-first lower insulating layer 310L_p may be formed on the carrier substrate 500.

The pre-first lower insulating layer 310L_p may be made of a photoimageable dielectric. The pre-first lower insulating layer 310L_p may include, for example, a photosensitive polymer. The photosensitive polymer may be formed of, for example, at least one of photosensitive polyimide, polybenzoxazole, phenolic polymer, and benzocyclobutene-based polymer.

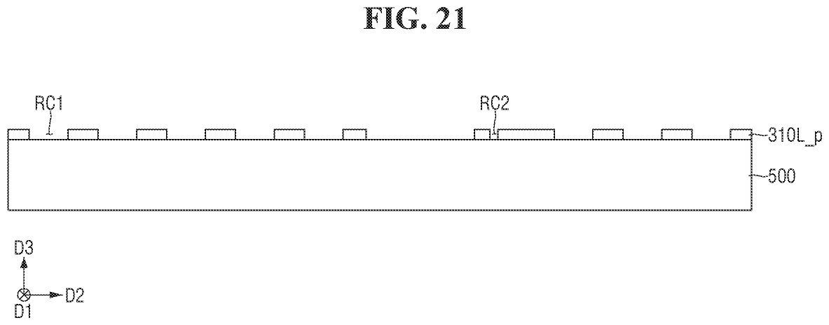

Referring to FIG. 21, a part of the pre-first lower insulating layer 310L_p may be etched.

First, although not shown, a mask film may be formed on the pre-first lower insulating layer 310L_p. The mask film may have an opening that approximately defines the positions of the ball pads (BP of FIG. 2) and the metal pattern (MP of FIG. 2). The mask film may be formed of a photoresist film, ACL (Amorphous Carbon Layer), SOH (Spin on Hardmask) or SOC (Spin on Carbon).

A part of the pre-first lower insulating layer 310L_p may be etched, using the mask film as an etch mask. A part of the pre-first lower insulating layer 310L_p may be etched to form a first recess RC1 and a second recess RC2. A width of the first recess RC1 may be smaller than a width of the second recess RC2, but is not limited thereto. The first recess RC1 and the second recess RC2 may be formed by the same process. Therefore, the depth of the first recess RC1 and the depth of the second recess RC2 may be the same as each other.

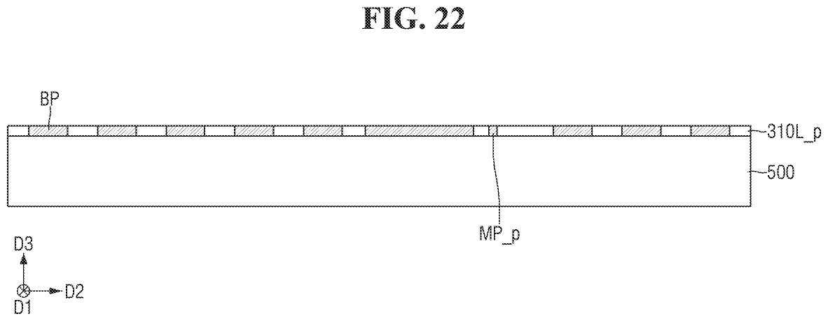

Referring to FIG. 22, a ball pad BP and a pre-metal pattern MP_p may be formed. The ball pad BP may be formed inside the second recess RC2. The pre-metal pattern MP_p may be formed inside the first recess RC1. The ball pad BP and the pre-metal pattern MP_p may each include a conductive material. As an example, the ball pad BP and the pre-metal pattern MP_p may each include copper (Cu).

Although not shown, a pre-metal layer that fills the first recess RC1 and the second recess RC2 and covers the pre-first lower insulating layer 310L_p may be formed. The pre-metal layer includes copper. The pre-metal layer is then etched to expose the upper surface of the pre-first lower insulating layer 310L_p. The pre-metal layer is etched to form the ball pad BP and the pre-metal pattern MP_p.

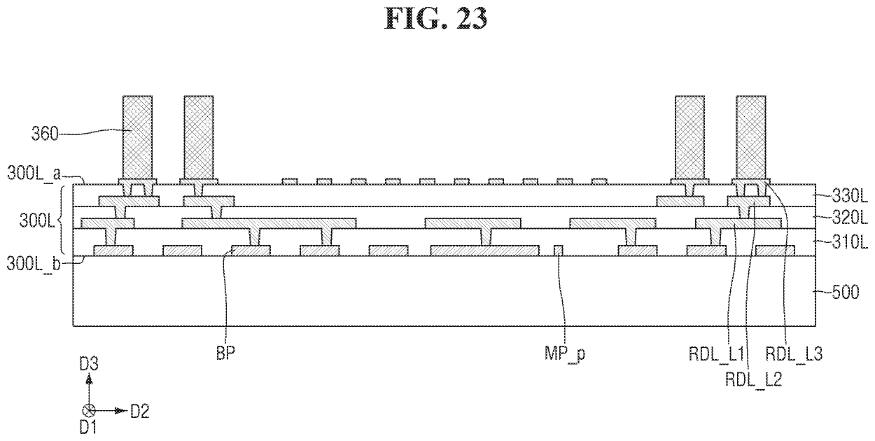

Referring to FIG. 23, a lower redistribution substrate 300L, first to third lower redistribution patterns RDL_L1, RDL_L2, and RDL_L3, and metal pillars 360 may be formed.

First, a first lower insulating layer 310L may be formed. A via portion of the first lower redistribution pattern RDL_L1 may be formed in the first lower insulating layer 310L. Subsequently, a second lower insulating layer 320L may be formed. A wiring portion of the first lower redistribution pattern RDL_L1 and a via portion of the second lower redistribution pattern RDL_L2 may be formed in the second lower insulating layer 320L. Subsequently, a third lower insulating layer 330L may be formed. A wiring portion of the second lower redistribution pattern RDL_L2 and a via portion of the third lower redistribution pattern RDL_L3 may be formed in the third lower insulating layer 330L. A wiring portion of the third lower redistribution pattern RDL_L3 may be formed on the third lower insulating layer 330L.

The lower redistribution substrate 300L includes first to third lower insulating layers 310L, 320L and 330L. The lower redistribution substrate 300L includes a first side 300L_a and a second side 300L_b that are opposite to each other. The first side 300L_a of the lower redistribution substrate 300L may be the upper surface of the third lower insulating layer 330L. The second side 300L_b of the lower redistribution substrate 300L may be the lower surface of the first lower insulating layer 310L.

Metal pillars 360 may be formed on the first side 300L_a of the lower redistribution substrate 300L.

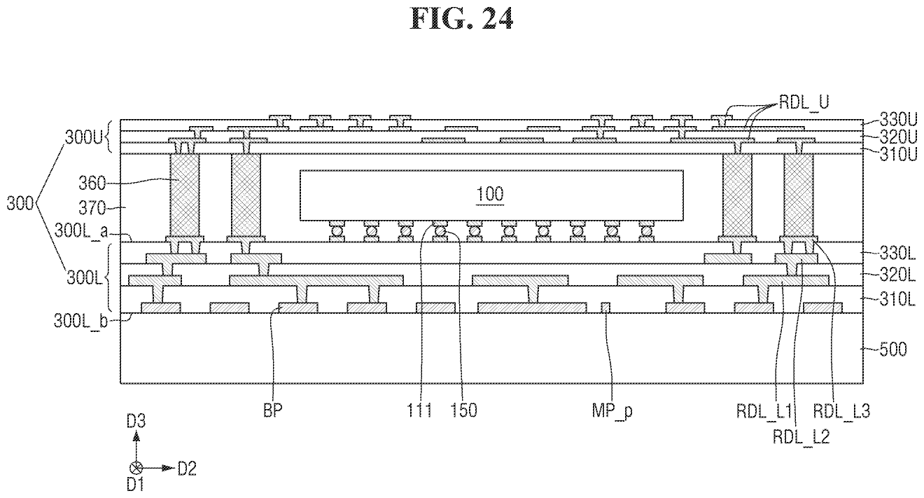

Referring to FIG. 24, the first semiconductor chip 100 may be mounted on the first side 300L_a of the lower redistribution substrate 300L. First, the second connection members 150 may land on the third lower redistribution patterns RDL_L3. Subsequently, the first semiconductor chip 100 may be mounted on the second connection members 150. The first chip pads 111 may be connected with the second connection members 150.

A molding film 370 may then be formed. The molding film 370 may cover the first semiconductor chip 100 and the metal pillars 360.

An upper redistribution substrate 300U may be formed on the molding film 370. The upper redistribution substrate 300U may include first to third upper insulating layers 310U, 320U and 330U. Upper redistribution patterns RDL_U may be formed inside the first to third upper insulating layers 310U, 320U and 330U.

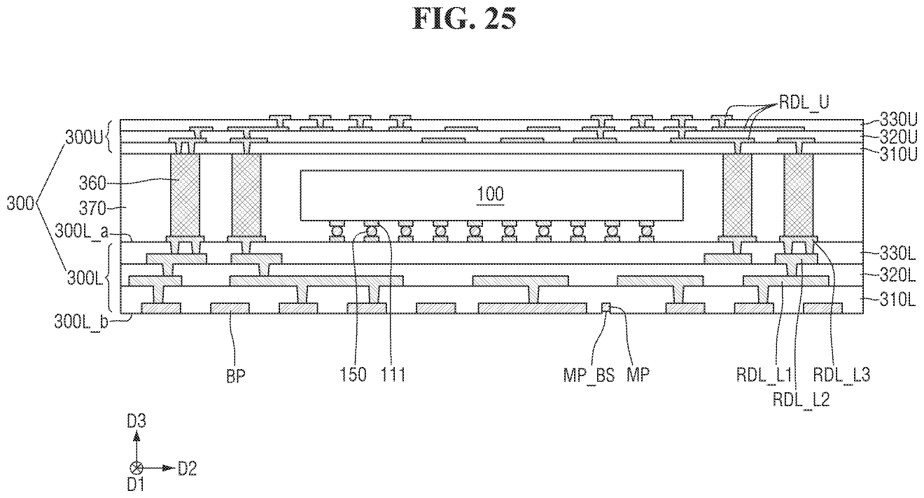

Referring to FIG. 25, the carrier substrate 500 may be removed. The carrier substrate 500 is removed to expose the second side 300L_b of the lower redistribution substrate 300L. While the second side 300L_b of the lower redistribution substrate 300L is exposed, the surface of the pre-metal pattern MP_p is exposed. Accordingly, a part of the pre-metal pattern MP_p may be etched. A part of the pre-metal pattern MP_p may be etched to form a metal pattern MP. Since a part of the pre-metal pattern MP_p is etched, the level of the bottom surface MP_BS of the metal pattern MP may be different from the level of the second side 300L_b of the lower redistribution substrate 300L.

The metal pattern MP may be formed of a single layer. As an example, the metal pattern MP may include, but not limited to, copper (Cu).

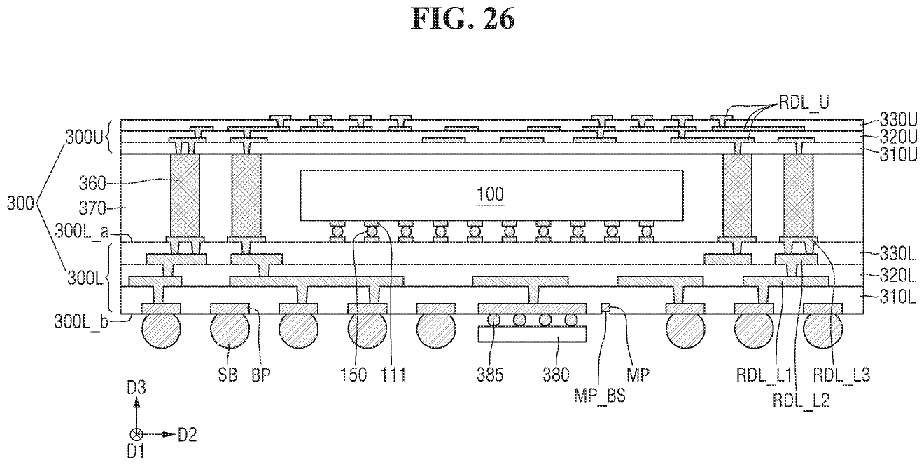

Referring to FIG. 26, a plurality of solder balls SB and a plurality of first connection members 385 may land on the second side 300L_b of the lower redistribution substrate 300L. The solder balls SB and the plurality of first connection members 385 may be connected to the ball pad BP. The silicon capacitor 380 may be mounted on the first connection members 385.

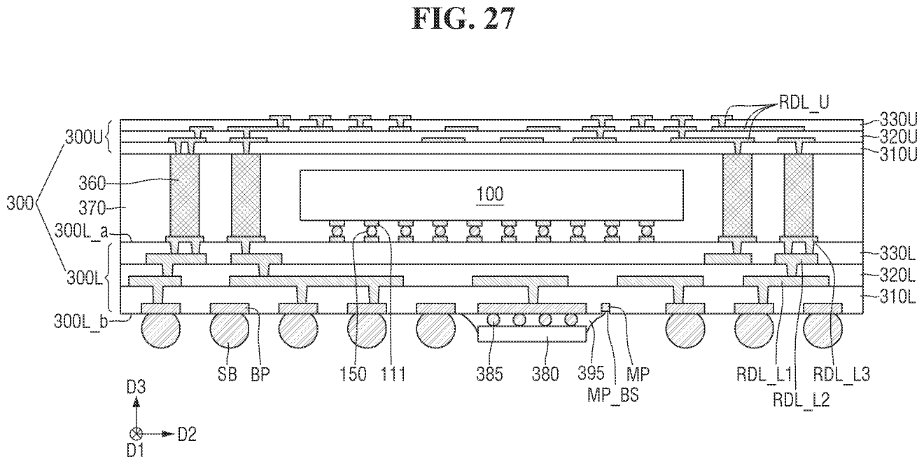

Referring to FIG. 27, the underfill 395 may be discharged. The underfill 395 may be discharged into the space between the silicon capacitor 380 and the metal pattern MP. The underfill 395 may be discharged to the second side 300L_b of the lower redistribution substrate 300L and flow into the space between the silicon capacitor 380 and the lower redistribution substrate 300L. The underfill 395 may fill the space between the silicon capacitor 380 and the lower redistribution substrate 300L.

The underfill 395 does not flow over the metal pattern MP. The underfill 395 does not flow over the metal pattern MP due to a difference in physical properties between the metal pattern MP and the lower redistribution substrate 300L. Accordingly, it is possible to prevent the solder balls SB from being contaminated with the underfill 395.

In concluding the detailed description, those skilled in the art will appreciate that many variations and modifications may be made to the preferred embodiments without substantially departing from the principles of the present disclosure. Therefore, the disclosed preferred embodiments of the disclosure are used in a generic and descriptive sense only and not for purposes of limitation.

What is claimed is:

1. A semiconductor package comprising:
a redistribution substrate comprising a first side and an opposite second side;
a semiconductor chip on the first side of the redistribution substrate;
a silicon capacitor on the second side of the redistribution substrate;
a plurality of solder balls on the second side of the redistribution substrate and adjacent the silicon capacitor; and
a metal pattern in the redistribution substrate and positioned between the silicon capacitor and the plurality of solder balls,
wherein the metal pattern comprises a first portion extending in a first direction, and a second portion connected to the first portion and extending in a second direction different from the first direction.

2. The semiconductor package of claim 1, wherein the metal pattern has at least one of a “U” shape and a rectangular shape in plan view.

3. The semiconductor package of claim 1, wherein a distance from the first side of the redistribution substrate to a bottom surface of the metal pattern is smaller than a distance from the first side of the redistribution substrate to the second side of the redistribution substrate.

4. The semiconductor package of claim 3, wherein the distance from the bottom surface of the metal pattern to the second side of the redistribution substrate is 5 μm or less.

5. The semiconductor package of claim 1, further comprising:
a plurality of connection members between the silicon capacitor and the redistribution substrate; and
an underfill surrounding the plurality of connection members between the silicon capacitor and the redistribution substrate,
wherein the underfill does not contact the metal pattern.

6. The semiconductor package of claim 1, further comprising:
a plurality of connection members between the silicon capacitor and the redistribution substrate; and
an underfill surrounding the plurality of connection members between the silicon capacitor and the redistribution substrate,
wherein the underfill contacts a portion of the metal pattern.

7. The semiconductor package of claim 1, wherein the metal pattern comprises a single layer.

8. The semiconductor package of claim 7, wherein the metal pattern comprises copper (Cu).

9. The semiconductor package of claim 1, wherein a length of the first portion of the metal pattern in the first direction is greater than a length of the silicon capacitor in the first direction.

10. The semiconductor package of claim 1, wherein the silicon capacitor has a rectangular shape in plan view, and
the metal pattern is adjacent a side surface of the silicon capacitor.

11. A semiconductor package comprising:
a redistribution substrate comprising a first side and an opposite second side;
a semiconductor chip on the first side of the redistribution substrate;
a silicon capacitor on the second side of the redistribution substrate, the silicon capacitor having a rectangular shape in plan view;
an underfill between the silicon capacitor and the redistribution substrate;
a plurality of solder balls on the second side of the redistribution substrate and adjacent the silicon capacitor, wherein the plurality of solder balls are not in contact with the underfill; and
a metal pattern within the redistribution substrate and adjacent a side surface of the silicon capacitor,
wherein the metal pattern has a “U” shape in plan view.

12. The semiconductor package of claim 11, wherein a distance from the first side of the redistribution substrate to a bottom surface of the metal pattern is smaller than a thickness of the redistribution substrate.

13. The semiconductor package of claim 12, wherein a distance from the bottom surface of the metal pattern to the second side of the redistribution substrate is 5 μm or less.

14. The semiconductor package of claim 11, wherein at least a part of the underfill is on at least a part of the metal pattern.

15. The semiconductor package of claim 11, wherein the underfill does not completely cover the metal pattern.

16. The semiconductor package of claim 11, wherein the metal pattern comprises a first sub-pattern, and a second sub-pattern spaced apart from the first sub-pattern, and
wherein a shape of the first sub-pattern is different from a shape of the second sub-pattern in plan view.

17. The semiconductor package of claim 11, wherein the metal pattern comprises a single layer comprising copper (Cu).

18. A semiconductor package comprising:
a redistribution substrate comprising a first side and an opposite second side;
a semiconductor chip on the first side of the redistribution substrate;
a silicon capacitor on the second side of the redistribution substrate, wherein the silicon capacitor has a rectangular shape in plan view;
a plurality of connection members between the silicon capacitor and the redistribution substrate;
an underfill surrounding the plurality of connecting members between the silicon capacitor and the redistribution substrate;
a plurality of solder balls on the second side of the redistribution substrate and adjacent the silicon capacitor; and
a single layer metal pattern within the redistribution substrate between the silicon capacitor and the plurality of solder balls,
wherein the metal pattern is adjacent a side surface of the silicon capacitor,
wherein the metal pattern comprises a first portion extending in a first direction, and a second portion connected to the first portion and extending in a second direction different from the first direction,
wherein a distance from the first side of the redistribution substrate to a bottom surface of the metal pattern is smaller than a distance from the first side of the redistribution substrate to the second side of the redistribution substrate, and
wherein at least a part of the metal pattern contacts at least a part of the underfill.

19. The semiconductor package of claim 18, wherein a distance from the bottom surface of the metal pattern to the second side of the redistribution substrate is 5 μm or less.

20. The semiconductor package of claim 18, wherein the metal pattern has a “U” shape in plan view.
